(19) United States
(12) Patent Application Publication
(10) Pub. No.: US 2010/0112493 A1
(43) Pub. Date: May 6, 2010

(54) Method for Producing a Plurality of Regularly Arranged Nanoconnections on a Substrate

(76) Inventors: Rainer Adelung, Kiel (DE); Seid Jebril, Kiel (DE); Mady Elbahri, Kiel (DE); Stefan Rehders, Schonkirchen (DE)

Correspondence Address: DIEDERIKS & WHITELAW, PLC, 13885 HEDGEWOOD DR., SUITE 317, WOODBRIDGE, VA, 22193, US

(21) Appl. No.: 12/085,637

(22) PCT Filed: Nov. 24, 2006
(86) PCT No.: PCT/DE2006/002068

§ 371 Date: Jan. 11, 2010

(30) Foreign Application Priority Data
Nov. 28, 2005 (DE) 10 2005 056 879.3

(51) Int. Cl. G03F 7/20

(52) U.S. Cl. 430/322

(57) ABSTRACT

A method for producing a plurality of regularly arranged nanoconnections on a substrate using an elastic masking layer forming cracks. Said method comprises the following steps: the masking layer is microstructured in order to produce at least one defined region provided with a masking over which the nanoconnections are to extend; cracks are produced in the masking layer; the material forming the nanoconnections is applied at least to the structures of the masking layer in the cracks and to the non-masked regions of the substrate; the masking layer with the is removed, and the defined region is covered with an essentially rectangular masking strip, over the width of which the nanoconnections are to extend the length of the strip being longer than the width; and a self-organized regular crack pattern comprising a plurality of crack lines is produced by inducing stress in the masking strip, such that a plurality of regularly arranged nanoconnections is formed over the at least one defined region.

The present invention relates to a method for producing a plurality of regularly arranged nanoconnections on a substrate. The present invention particularly relates to the production of a regular arrangement of conducting nanowires, which likewise connect surfaces which are conducting but otherwise not in contact with one another. Hence, the present invention relates to devices which allow measurement of the electrical conductivity of nanoconnections depending on environmental parameters, in particular devices that may be used as sensors.

Nanowires (also: quantum wires) typically exhibit lengths of several micrometers with diameters in the nanometer range. Such wires are manifestly in demand for further miniaturization of integrated circuits, but also exhibit novel properties as a result of the quantum effects that occur. In addition, they offer the possibility of producing highly sensitive sensors, catalytic surfaces, or optically transparent electrical conductors. Nanowires may have atomic-scale gaps, so called nanogaps. The incorporation of chemicals and/or closure of the nanogaps by expansion of the metal (e.g. by changes in temperature or hydrogen absorption) directly results in a change in conductivity.

The ability to produce nanowires on special or even any substrates and arrange them systematically is therefore a current research topic. Typical methods that have currently been used are characterized by extremely high costs or are very slow because they structure serially, like electron beam lithography or photolithography, for example.

The arrangement and orientation of nanowires on a substrate is extremely difficult because hardly any suitable tools for targeted manipulation of nanoparticles are available. Usual microstructuration methods like photolithography, for example, fail with quantum wires in that the required structural dimensions are clearly smaller than the beam diameter and the light cannot be easily focused. Therefore, many methods are geared toward the self-organization of metal atoms or clusters on the substrate, in which the wires form automatically. However, in most cases this can be achieved only under very special conditions.

U.S. 2003/0008505 A1 teaches that in order to produce parallel wires, the nanowires of a desired crystalline configuration have to be arranged on a special crystalline substrate. The nanowire and substrate should have as good as possible a match of lattice constants in one direction on the substrate surface, whereas the “lattice mismatch” should be very great in all other directions. The nanowires then form in a self-organized manner during epitactic growth.

CA 2 322 254 also discloses how to coat nanowires magnetically and apply them in a liquid mixture to the substrate in order to align them in the field there. Subsequent hardening of the mixture produces a layer with parallel wires on the substrate.

Direct deposition of structures basically on any substrate where nanowires are to form by self-organization was proposed in DE 100 19 712 AI. For this purpose, a standing compression wave is applied along the substrate surface, so that mobile atoms on the substrate preferably converge on the nodal regions of the wave, where they form the nanowires.

On the other hand, DE 42 18 650 AI proposes growing semiconductor segments epitactically in the mask recesses of a masked substrate. The nanowires should appear along the edges they form with the substrate and/or mask. In this case, the fundamental idea is to form a nanowire network along the lines of conventional masking methods.

According to DE 198 52 585, nanowires may form on multilayer crystal surfaces. Without any pretreatment of the substrate, vapor-deposited atoms, e.g. rubidium, move on a layered crystal surface until they reach a naturally occurring edge. They move along the edge and spontaneously adhere to a nanowire or a nanowire network. A nanowire network with a mesh width in the micrometer range is formed in a few minutes.

The above methods have the disadvantages that they either cannot be used on technically relevant substrates, or require considerable expense for presetting the structures on any desired substrate, so that a cost-effective implementation for mass production, in particular of sensors, may hardly be expected.

The article by Adelung et al. nature materials, Vol. 3, June 2004, pp. 375-379, describes a relatively simple way of applying a nanostructure, in particular a nanowire, on a substrate, where this is accomplished following microscopic prestructuration. For this purpose, the substrate is first coated by means of a wet chemical or vapor deposition method, e.g. with a brittle oxide film or a polymer, and subsequently cracks that reach the substrate are systematically generated on this film. For example, by means of vapor deposition e.g. metal atoms are finally applied to the substrate with the cracked film, where metal accumulations may form directly on the substrate only in the region of the cracks. If necessary, the film can be removed so that only these nanowires are left. Depending on the demarcated crack structure, more complex nanowire networks may be generated, a rectangular grid, for example.

In their article, Adelung et al. offers different proposals as to how certain crack patterns can be generated on the layer (as a masking layer). The trigger of the crack formation is always thermal or mechanical stress that acts on the masking layer. In order to predetermine the course of the cracks, it is recommended that mechanically weak areas be provided in the masking layer, which can be generated by means of microstructuration methods. In particular, a way of generating a single nanowire as an electrical connection between two extensive metallized surfaces is presented.

This construction already implements an elementary nanowire sensor. However, it cannot be assumed that a similar nanowire with the same electrical properties will result on each repetition of the production process. For industrial production it would rather be necessary to be in control of the statistical variance of the nanowire properties, i.e. each sensor should be provided with a plurality of nanoconnections so that on average a reproducible device may be produced. This implicitly requires that the cracks in the masking layer have an adequately uniform course and similar crack profiles.

If the suggestions made by Adelung et al. are observed, it would be possible to produce several parallel nanowires by weakening and breaking down the adjacent areas of the masking layer by means of microstructuration. This entails an increased structuration effort and a minimum distance between the cracks (and hence the wires) in the micrometer range. Furthermore, it cannot be assumed that the cracks are uniform; their openings may have different widths, for example. Alternatively, it is proposed that an area with a homogeneous masking layer be broken down by bending the substrate, so that a plurality of parallel cracks form in a narrow space. However, this is not an advantageous procedure, at least in silicon technology.

Therefore, it is the object of the present invention to create a method with which a regular arrangement of nanoconnections can be produced on a substrate that is compatible with silicon technology, demanding only low expenditures for microstructuration.

The object is achieved by a method according to the characteristics described in the main claim. The subclaims describe advantageous embodiments.

The present invention uses an effect known per se, that a fixed strip made of elastic material tends to form regular buckling patterns when it is subjected to compression in the plane of the strip. This effect occurs due to self-organization on an otherwise uniform strip, in particular of homogeneous thickness, without further measures for presetting the structure (in this regard see Audoly et al., “Secondary buckling patterns of a thin plate under in-plane compression,” Eur. Phys. J. B 27, 7-10 (2002)).

According to the present invention, the said effect is transferred to the masking layer in order to produce regular crack patterns in a self-organized manner. As the nanoconnections have to be produced between two areas extensively covered with nanowire material, these areas will be produced—as already described in prior art—simultaneously with the nanoconnections. For this purpose, the substrate, in particular a silicon wafer, will first be provided with a masking layer, which will subsequently be removed in the region of both said areas. Between the exposed areas a narrow strip (a few micrometers in width, several micrometers in length) will first be maintained, over whose width the nanoconnections are to be formed. By inducing thermal stress which acts on the substrate at least in the region of the remaining masking strip, a regular crack structure will likewise be produced analogously to the above regular buckling of the material. In the process, several similar cracks form, which are arranged next to one another on the strip and cross the entire width of the strip. In general, the generated crack pattern along the length of the strip is configured periodically. The aspect ratio (length:width) of the masking strip must be significantly greater than one for the process to be implemented.

The invention is exemplified with reference to the following figures. The figures show:

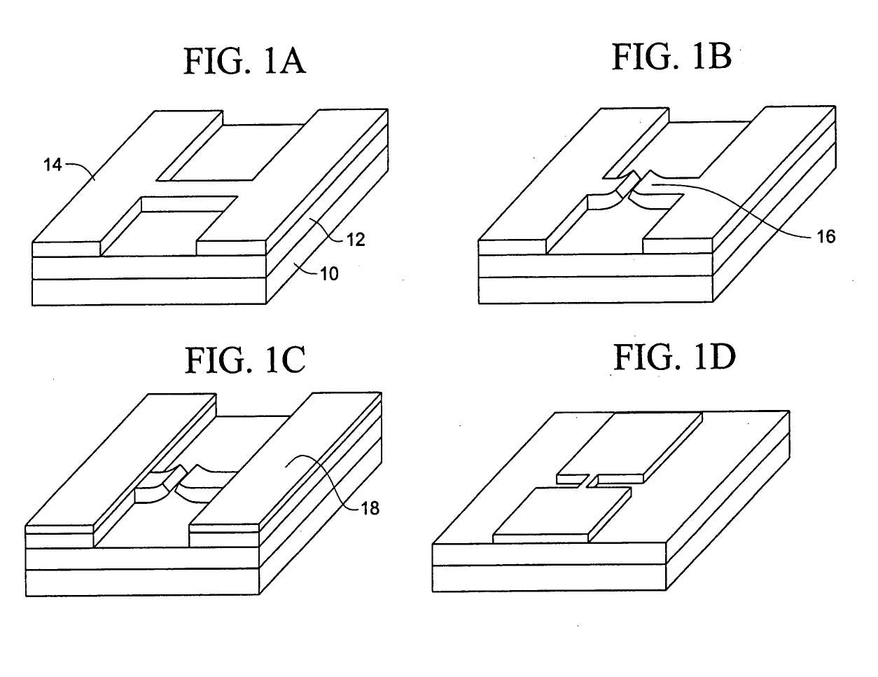

FIG. 1 a schematic drawing for producing a single nanoconnection between two metallized surfaces,

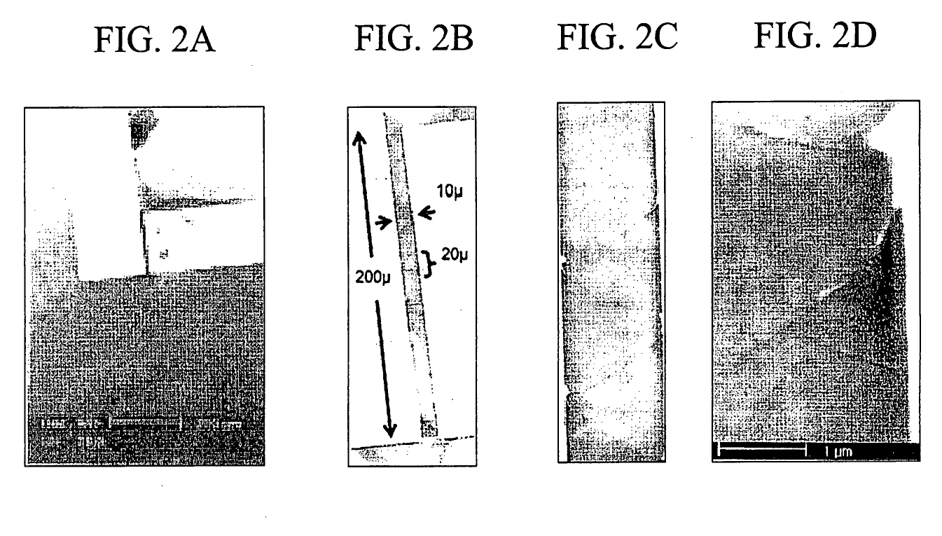

FIG. 2 electron microscope images of a masking strip at different magnifications with regular cracks produced according to the teachings of the present invention,

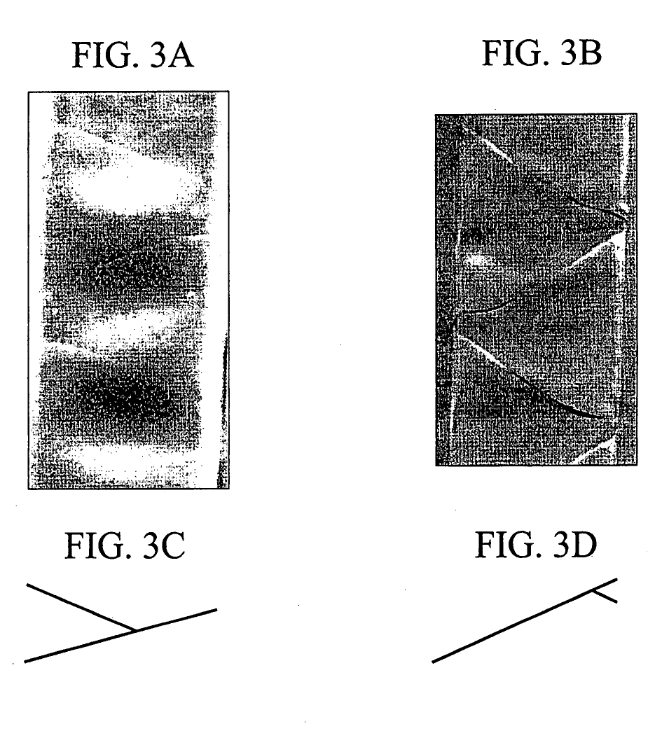

FIG. 3 two examples of crack patterns which may be produced by varying the dimensions of the masking layer.

FIG. 1a) shows a substrate 10, preferably a silicon wafer, which is covered with an electrical insulation layer 12 (in this case SiO₂, for example), on which a microstructured masking layer 14 has already been formed. The masking layer will preferably be a light-sensitive lacquer which is treated by means of photolithography and removed at predefined places in an essentially known manner. The remaining masking is distinguished by a strip which separates two exposed extensive areas of the substrate and/or insulation layer surfaces from one another.

FIG. 1b) shows a crack across the strip, as a result of which a small width of the substrate is exposed below the strip. It is not unusual for the masking material to detach (delaminate) slightly in the region of the crack. In fact, this delamination 16 is even very advantageous and should be promoted, possibly by providing adequately thick masking layers, which tend to form internal stresses. The selection of polymers with a high thermal expansion coefficient as the masking material, or their addition to it, is an advantageous embodiment of the invention as well.

FIG. 1c) shows the result of deposition 18 of material (noble metals will preferably be applied for nanowire sensors) on the structure shown in FIG. 1b). If the mask with the material applied thereto is now removed, the exposed nanowire, which is provided with extensive contacts on both ends (FIG. 1d)), will remain on the substrate.

It should be noted that the crack formation shown in FIG. 1b) is induced by stress in the masking layer acting parallel to the course of the strip. It cannot be expected that several cracks will just form along the strip, or that they will form a regular pattern. The experimental discovery that the above self-organization of deformations of clamped material strips can also be transferred to such masking strips, and that the producibility of regularly arranged nanoconnections in industrial processes is hence coming into reach, is the central idea of the present invention.

FIG. 2 shows electron microscope images of a masking strip cracked according to the present invention in four different magnifications. The periodic repetition of a basic pattern running along the strip is clearly visible. The basic pattern comprises a long crack across the strip at about a 45° angle with respect to the edge of the strip and a small crack bifurcation close to each edge of the strip, which is clearly visible in the two largest magnifications.

Said basic pattern may be varied according to the present invention in that the dimensions of the masking strip are controlled. FIG. 3c) shows the basic patterns that form with different strip widths (taken from SEM images, which are shown as FIG. 3a) and b)). The crack density, i.e. the number of nanoconnections per length unit of the masking strip, clearly can be adjusted. It is further evident that the total length of all nanoconnections can not only be readily measured, but can even be specifically adjusted by means of the method according to the invention.

### EXEMPLARY EMBODIMENT

Commercially available Shipley lacquer S 1813 is spin coated with a 550-nm thickness in a closed system on a silicon wafer with an SiO₂ insulation layer. For this purpose, the masked substrate is exposed for 20 minutes to an HMDS (hexamethyldisiloxane) bonding agent. The masking layer is subsequently microstructured by means of photolithography, while the microstructures are tempered during production at 100 ° C. for 30 min, exposed for 2 sec, and developed for 30 sec.

In the simplest case, the regions of the substrate that are exposed after the development consist of two square fields of about 1 mm² , from each of which a channel measuring 200 pm in width branches off. These channels converge but do not touch; rather, they are kept apart by a photoresist strip measuring 8-10 μm in width. In FIG. 2a) the channels can be seen as white surfaces. The square fields are not shown.

The mask structure that has formed is now heated together with the substrate on a burner at 90° C. for 30 min. Immediately afterward, the photoresist is exposed to a cold gas flow for about 3 min. This takes place in liquid nitrogen vapor, which comes out of a hole in a container filled with liquid nitrogen. Subsequently, the samples are warmed to room temperature again. This process results in thermal stresses, which lead to cracks and delamination in the photoresist. A zigzag-shaped periodic crack pattern results that connects both channels. The diameter of the cracks is in the nanoscale range and may be modified by further treatment steps such as heating. In the example of FIG. 2 the cracks are evenly distributed over the 200-μm width of the channel and thus are separated from one another by about 20 μm (cf. FIG. 2b)). Their length is about 14.2 μm. Subsequent metallization by means of chrome evaporation as a bonding agent, for example, and subsequent sputter deposition with noble metal will fill the square surfaces, channels and cracks with metal. The photoresist is removed by exposure to acetone for a few minutes. Subsequent immersion of the structures in an ultrasonic bath filled with acetone for 1-2 seconds removes the excess metal and concludes the process. All nanowires produced this way have a diameter of 50 to 100 nm.

Finally, it should be pointed out that the production of nanowire sensors with conducting nanowires described here for purposes of motivation should not be understood as a restriction of the invention. The method according to the present invention for producing crack patterns in masking surfaces is clearly very suitable for the production of nanoconnections of any materials, in particular semiconductors or insulators, for example ceramics. The only requirement for the material is that it can be applied to the substrate in particle sizes small enough that it can penetrate the cracks in the masking and adhere to the substrate below without difficulty. However, this does not represent an excessive restriction.

The study of possible ways of controlling the different crack patterns which can form on the masking strips is assuredly not yet concluded. What has concretely been demonstrated for now is only the dependency on strip dimensions; however, a plurality of further parameters may likewise play a role, for example:
absolute temperatures to which the masked substrate is exposed,
temperature gradients regarding the heating or cooling time,
the composition of the material for the mask, in particular admixtures,
additional force effects on the mask, e.g. ultrasonic bombardment in a protective gas atmosphere.

What is common to these possible embodiments is that they may in general dispense with costly manipulations at micrometer or even submicrometer scales. To be sure, their applicability is based on the transfer of the self-organized regular structure into the mask material, accomplished for the first time, combined with the production of nanowires as a result of the systematic formation of cracks in such masks. Hence, the present invention may be regarded as a key concept for the production of regularly arranged nanoconnections on substrates in industrial production processes.

1. A method for producing a plurality of regularly arranged nanoconnections on a substrate using a crack-forming elastic masking layer including the following steps:
microstructuration of the masking layer for producing at least one defined masked region, over which the nanoconnections should extend,
production of cracks in the masking layer,
application of the material that forms the nanoconnections on at least the structures of the masking layer, into the cracks as well as on the non-masked regions of the substrate,
lift-off of the masking layer with the material applied thereto,
wherein the at least one defined masked region is covered with an essentially rectangular masking strip, over whose width the nanoconnections should extend, the length of the strip being larger than its width, and
wherein a self-organized regular crack pattern comprising a plurality of crack lines is formed by inducing stress in the masking strip so that a plurality of regularly arranged nanoconnections are formed over the at least one defined region.

2. The method according to claim 1, characterized in that the self-organized regular crack pattern is predefined by selecting the dimensions of the masking strip.

3. A method according to claim 1, characterized in that thermal stress is induced in the masking strip by alternately heating and cooling the substrate with the masking strip.

4. The method according to claim 3, characterized in that the substrate with the masking layer is heated on a burner and cooled by means of cold gassing.

5. A method according to claim 1, characterized in that the masking layer is composed of a light-sensitive material, and microstructuration takes place by means of photolithography.

6. A method according to claim 1, characterized in that the masking layer is formed in such a way that the masking layer detaches from the substrate along the plurality of crack lines.
